(19) United States
(12) Patent Application Publication
(10) Pub. No.: US 2022/0066587 A1
(43) Pub. Date: Mar. 3, 2022

(54) TOUCH DISPLAY PANEL AND ELECTRONIC DEVICE

(71) Applicant: SHENZHEN ROYOLE TECHNOLOGIES CO., LTD., Shenzhen (CN)

(72) Inventors: Jiahao KANG, Shenzhen (CN); Ze YUAN, Shenzhen (CN); Jigang ZHAO, Shenzhen (CN); Wenbing HU, Shenzhen (CN)

(21) Appl. No.: 17/446,162

(22) Filed: Aug. 26, 2021

(30) Foreign Application Priority Data
Aug. 26, 2020 (CN) 202010872089.6

(51) Int. Cl. G06F 3/041; G06F 3/044; H01L 27/32

(52) U.S. Cl. CPC G06F 3/0412; G06F 3/0443; G06F 3/04164; G06F 2203/04107; H01L 27/323; H01L 27/3272; G06F 3/04166

(57) ABSTRACT

The present disclosure relates to a touch display panel and an electronic device. The touch display panel includes: a substrate; and a light-emitting unit layer located on one side of the substrate, where the light-emitting unit layer includes a cathode metal layer, the cathode metal layer forms first touch electrodes and second touch electrodes, and the first touch electrodes are insulated from the second touch electrodes to form a mutual capacitive touch electrode. The touch electrodes of the touch display panel according to the present disclosure are shared with the cathode metal layer, so that the touch display panel is more integrated and has a smaller thickness.

### TECHNICAL FIELD

The present disclosure relates to the field of touch display, and in particular, to a touch display panel and an electronic device.

### BACKGROUND

With the development of a flexible display technology, a touch screen is required to be as integrated and miniaturized as possible. At present, most of mutual capacitive touch display screens are in modes of add-on or on-cell, and have disadvantages of large thickness, complex structure, a large number of adhesive structures and processes and high preparation costs. In addition, there are also disadvantages that are not conducive to bending of the screens and further integration and miniaturization of an electronic device.

### SUMMARY

In view of this, the present disclosure provides a touch display panel, where touch electrodes of the touch display panel are shared with a cathode metal layer, so that the touch display panel is more integrated and has a smaller thickness.

An embodiment of the present disclosure provides a touch display panel, including:

a substrate; and

a light-emitting unit layer located on one side of the substrate, wherein the light-emitting unit layer includes a cathode metal layer, the cathode metal layer forms first touch electrodes and second touch electrodes, and the first touch electrodes and the second touch electrodes are insulated from each other and form a mutual capacitive touch electrode.

Optionally, the light-emitting unit layer has a light-emitting period, and the light-emitting period includes a first time and a second time staggered from the first time; at the first time, the first touch electrodes each are configured to receive a touch drive signal, the second touch electrodes each are configured to receive a touch induction signal, or at the first time, the second touch electrodes each are configured to receive the touch drive signal, and the first touch electrodes each are configured to receive the touch induction signal; and at the second time, the first touch electrodes and the second touch electrodes are each configured to receive a display drive signal.

Optionally, the first touch electrodes and the second touch electrodes are arranged at a same layer.

Optionally, the touch display panel further includes a first connecting part and a second connecting part, where the adjacent first touch electrodes are electrically connected to each other through the first connecting part, the adjacent second touch electrodes are electrically connected to each other through the second connecting part, and the second connecting part is crossed with and insulated from the first connecting part.

Optionally, the first connecting part is arranged at the same layer as the first touch electrodes and the second touch electrodes, and the first connecting part avoids sub-pixels of the light-emitting unit layer.

Optionally, the second connecting part is located between the substrate and the second touch electrode.

Optionally, an insulating layer is arranged between the second touch electrode and the second connecting part, the insulating layer is provided with a through hole, and the second touch electrode is electrically connected to the second connecting part by filling the through hole with a conductive material.

Optionally, the through hole includes a first hole position and a second hole position, the first hole position is filled with a first conductive material, and the second hole position is filled with a second conductive material.

Optionally, the light-emitting unit layer includes light-emitting units arranged in an array, the light-emitting units each include an anode, the first conductive material is the same as a material of the anode, and the second conductive material is the same as a material of the cathode metal layer.

Optionally, the light-emitting unit layer includes light-emitting units arranged in an array, the light-emitting units each include an anode, the anode is located between the substrate and the cathode metal layer, and the second connecting part and the anode are at a same layer and are insulated from each other.

Optionally, the touch display panel further includes a metal wire, where the metal wire is located between the substrate and the cathode metal layer, and the second connecting part and the metal wire are at a same layer and are insulated from each other.

Optionally, the touch display panel further includes a source and a drain, where the source and the drain are insulated from each other and arranged at a same layer at an interval, and the source and the drain are located between the substrate and the light-emitting unit; and the second connecting part is at the same layer as the source and the drain and is insulated from the source and the drain.

Optionally, the touch display panel further includes a gate, where the gate is located between the substrate and the light-emitting unit, and the second connecting part and the gate are at a same layer and are insulated from each other.

Optionally, the touch display panel further includes a light shielding layer, where the light shielding layer is located on a surface of the substrate facing the light-emitting unit, and the second connecting part and the light shielding layer are at a same layer and are insulated from each other.

The present disclosure further provides an electronic device, including:

a device body; and

the above-mentioned touch display panel, where the touch display panel is arranged on the device body.

Therefore, in the touch display panel according to the present disclosure, the cathode metal layer is patterned to form first touch electrodes and second touch electrodes of a touch panel, thereby integrating the touch panel into a display panel, so that the touch display panel is better integrated and has a smaller thickness.

### BRIEF DESCRIPTION OF DRAWINGS

To illustrate structural features and functions of the present disclosure more clearly, the following detailed description will be made with reference to the accompanying drawings and specific embodiments.

FIG. 1 is a schematic cross-sectional structural diagram illustrating a touch display panel according to an embodiment of the present disclosure;

FIG. 2 is a schematic structural diagram illustrating a cathode metal layer according to the embodiment of FIG. 1 in the present disclosure;

FIG. 3 is a partial enlarged view illustrating a region A of the cathode metal layer according to the embodiment of FIG. 2 in the present disclosure;

FIG. 4 is a schematic cross-sectional structural diagram illustrating a touch display panel according to another embodiment of the present disclosure;

FIG. 5 is a schematic diagram illustrating the distribution of touch drive signals and display drive signals in each light-emitting period of a touch display panel according to an embodiment of the present disclosure;

FIG. 6 is a schematic diagram illustrating the distribution of touch drive signals and display drive signals in each light-emitting period of a touch display panel according to another embodiment of the present disclosure;

FIG. 7 is a partial enlarged view illustrating a cathode metal layer according to an embodiment of the present disclosure;

FIG. 8 is a schematic cross-sectional structural diagram illustrating a touch display panel according to another embodiment of the present disclosure;

FIG. 9 is a schematic cross-sectional structural diagram illustrating a touch display panel according to another embodiment of the present disclosure;

FIG. 10 is a schematic cross-sectional structural diagram illustrating a touch display panel according to another embodiment of the present disclosure;

FIG. 11 is a schematic cross-sectional structural diagram illustrating a touch display panel according to another embodiment of the present disclosure;

FIG. 12 is a schematic cross-sectional structural diagram illustrating a touch display panel according to another embodiment of the present disclosure; and

FIG. 13 is a schematic structural diagram illustrating an electronic device according to an embodiment of the present disclosure.

### DESCRIPTION OF EMBODIMENTS

The technical solutions in the embodiments of the present disclosure will be clearly and completely described below in conjunction with the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

A touch display panel 100 is a display panel integrating a touch function and a display function. Touch screens roughly fall into four types: infrared touch screens, resistive touch screens, surface acoustic wave touch screens and capacitive touch screens. Capacitive touch screens fall into self-capacitive touch screens and mutual capacitive touch screens.

The self-capacitive touch screens each are implemented by using a transparent conductive material (such as indium tin oxide (ITO)) to make horizontal and vertical electrode arrays on a surface of glass. These horizontal and vertical electrodes form capacitors with the ground respectively. When a finger touches the capacitive screen, the capacitance of the finger will be superimposed on the capacitance of a screen body to increase the capacitance of the screen body.

The mutual capacitive touch screens each are implemented by using two metals or metal oxide materials to form a set of parallel electrode patterns (at a same layer or different layers). Because the distance between the two electrodes is very close, a capacitor is formed. When the finger touches the corresponding electrode, the capacitance between the two electrodes changes.

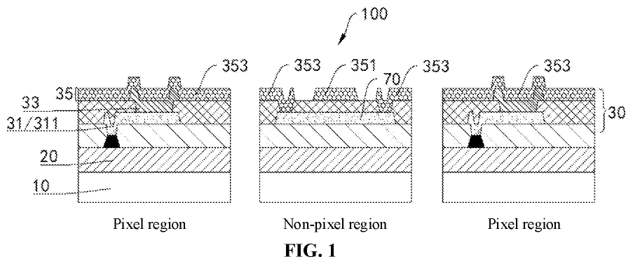

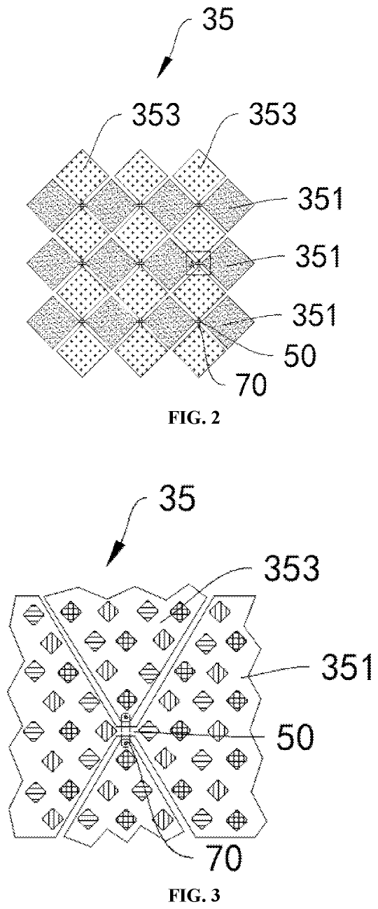

Referring to FIG. 1 to FIG. 3, the touch display panel 100 according to an embodiment of the present disclosure includes: a substrate 10; and a light-emitting unit layer 30 located on one side of the substrate 10, wherein the light-emitting unit layer 30 includes a cathode metal layer 35, the cathode metal layer 35 forms first touch electrodes 351 and second touch electrodes 353, and the first touch electrodes 351 are insulated from the second touch electrodes 353. The first touch electrodes 351 and the second touch electrodes 353 form a mutual capacitive touch electrode. In the touch display panel 100 according to the present disclosure, the cathode metal layer 35 is patterned to form the first touch electrodes 351 and the second touch electrodes 353, thereby integrating a touch panel into a display panel, so that the touch display panel 100 is better integrated and has a smaller thickness.

Optionally, the substrate 10 may be a glass substrate, or a substrate implemented by depositing a polyimide (PI) flexible substrate on a glass substrate, or the like.

Specifically, the light-emitting unit layer 30 includes an anode layer 31, a light-emitting layer 33 and a cathode metal layer 35 that are stacked in sequence. The anode layer 31 is disposed adjacent to the substrate 10, and the anode layer 31 includes multiple anodes 311 arranged in an array. The light-emitting layer 33 includes light-emitting parts arranged in an array. One light-emitting part corresponds to one anode 311. Each of the light-emitting parts forms one sub-pixel. Three adjacent sub-pixels that can emit red, blue and green light respectively are formed in one pixel. A color and brightness of the pixel can be adjusted by controlling the proportion of the red, blue and green light of the three sub-pixels. The cathode metal layer 35 covers the entire light-emitting layer 33.

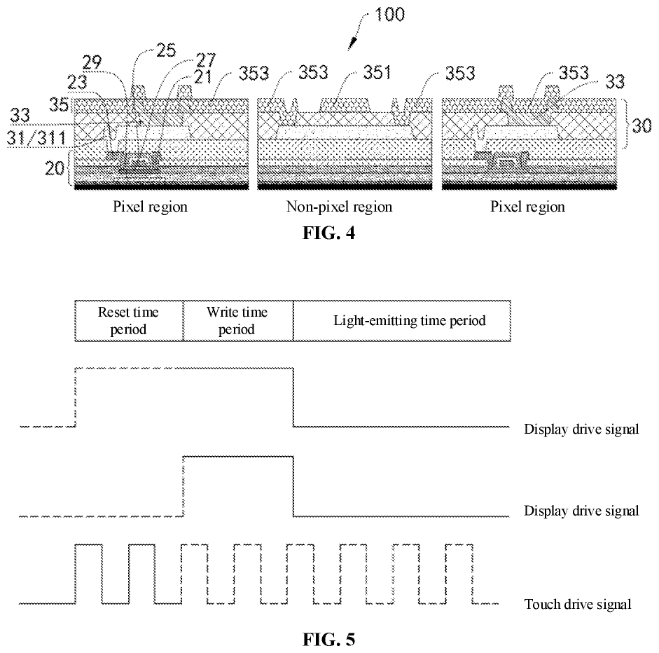

Optionally, referring to FIG. 4, in some embodiments, the touch display panel 100 according to the present disclosure further includes a drive circuit 20, where the drive circuit 20 is located between the substrate 10 and the light-emitting unit layer 30, and is configured to drive the light-emitting unit layer 30 to emit different colors of light.

Specifically, the drive circuit 20 includes thin-film transistors arranged in an array, and the thin-film transistors each include a source 21, a drain 23, a gate 25 and an active layer 27. The source 21 and the drain 23 are arranged at a same layer at an interval, and are separately connected to the active layer 27. The source 21 or the drain 23 is electrically connected to the anode 311 of the light-emitting unit layer 30, and the gate 25 is insulated from the active layer 27 at a different layer, and is configured to access a gate signal. Specifically, the thin-film transistor may have a top gate structure or a bottom gate structure. When the thin-film transistor has the top gate structure, the drive circuit 20 further includes a light shielding layer 29. The light shielding layer 29 is located between the substrate 10 and the active layer 27, and is configured to prevent light from entering the active layer 27 from one side of the substrate 10 that faces away from the drive circuit 20 and affecting a signal of the drive circuit 20.

Optionally, the source 21, the drain 23 and the gate 25 may be, but are not limited to, metals such as titanium (Ti), aluminum (Al), molybdenum (Mo), copper (Cu) and gold (Au) or metal alloys, respectively, or the like.

Optionally, the active layer 27 may be, but is not limited to, a semiconductor layer such as amorphous silicon (a-Si), polysilicon (p-Si) or a metal oxide.

Optionally, in some embodiments, the light-emitting unit layer 30 has a light-emitting period, and the light-emitting period includes a first time and a second time staggered from the first time. At the first time, the first touch electrodes 351 each are configured to receive a touch drive signal, the second touch electrodes 353 each are configured to receive a touch induction signal, or at the first time, the second touch electrodes 353 each are configured to receive the touch drive signal, and the first touch electrodes 351 each are configured to receive the touch induction signal. At the second time, the first touch electrodes 351 and the second touch electrodes 353 each are configured to receive a display drive signal, that is, the first touch electrodes 351 and the second touch electrodes 353 may be connected to a low level or grounded at the second time.

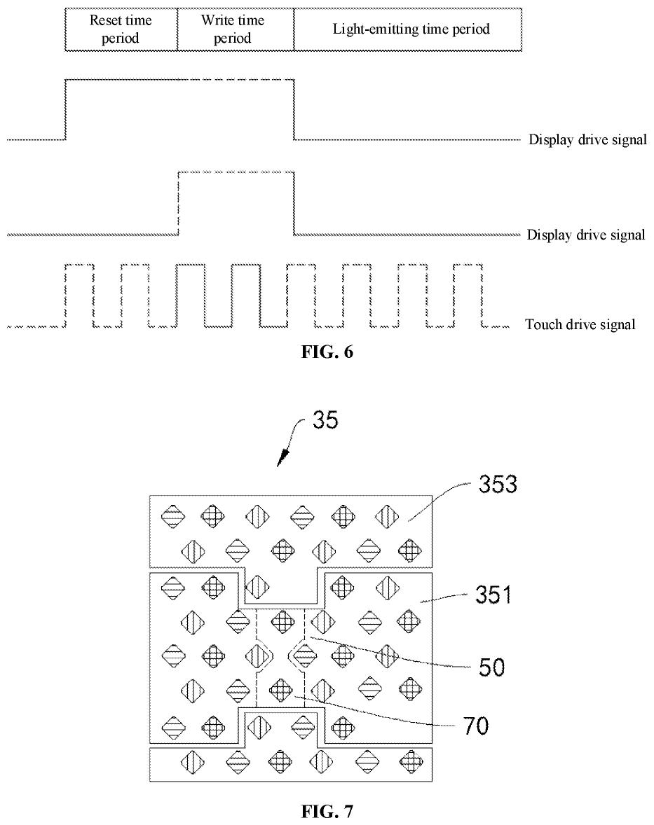

Specifically, referring to FIG. 5 and FIG. 6, the light-emitting period includes a reset time period, a write time period and a light-emitting time period; the first time is within the reset time period or the write time period, or spans the reset time period and the write time period. When the light-emitting period is within the reset time period and the write time period, the cathode metal layer 35 does not need to be connected to a fixed voltage. During this time period, a pixel circuit is in an off state (black), a pixel circuit data signal is stored in a storage node (Nst), and an original data signal is returned after the input of a touch drive signal is stopped, i.e., after a touch period ends. Therefore, accessing the touch drive signal in any time period within the reset time period and the write time period does not affect a normal display function of the touch display panel 100.

In the embodiment of FIG. 5, the first time is within the reset time period. During the reset time period, the first touch electrode 351 accesses a touch drive signal, and the second touch electrode 353 accesses a touch induction signal; and the cathode metal layer 35 accesses a display drive signal during the write time period and the light-emitting time period.

In the embodiment of FIG. 6, the first time is within the write time period. During the write time period, the first touch electrode 351 accesses a touch drive signal, and the second touch electrode 353 accesses a touch induction signal; and the cathode metal layer 35 accesses a display drive signal during the reset time period and the light-emitting time period.

Optionally, in some embodiments, the first touch electrodes 351 and the second touch electrodes 353 are arranged at a same layer. The term “same layer” in the present disclosure, unless otherwise specified, means that when the touch display panel 100 is prepared, two components are formed in a same process or process step.

Referring to FIG. 1 to FIG. 3 again, in some embodiments, the touch display panel 100 according to the present disclosure further includes a first connecting part 50 and a second connecting part 70, where the adjacent first touch electrodes 351 are electrically connected to each other through the first connecting part 50, the adjacent second touch electrodes 353 are electrically connected to each other through the second connecting part 70, and the second connecting part 70 is crossed with and insulated from the first connecting part 50. Specifically, the first touch electrodes 351 and the second touch electrodes 353 are separately arranged in an array, the first connecting part 50 electrically connects the first touch electrodes 351 to form multiple first touch electrode chains arranged in a first direction, and the second connecting part 70 electrically connects the second touch electrodes 353 to form multiple second touch electrode chains arranged in a second direction, each of the first touch electrode chains is crossed with and insulated from all second touch electrode chains, and each of the second touch electrode chains is crossed with and insulated from all first touch electrode chains, where the first direction is crossed with the second direction.

Specifically, in some embodiments, the first connecting part 50 is arranged at the same layer as the first touch electrodes 351 and the second touch electrodes 353, the first connecting part 50 is formed by the cathode metal layer 35, and the first connecting part 50 avoids sub-pixels of the light-emitting unit layer 30, that is, the first connecting part 50 avoids the light-emitting part, or an orthographic projection of the first connecting part 50 on the substrate 10 and an orthographic projection of the light-emitting part on the substrate 10 have no overlapped region or are staggered. In this case, the cathode metal layer 35 may be made of a transparent conductive material.

Referring to FIG. 7, in some embodiments, the first connecting part 50 may be formed by the cathode metal layer 35, and the first connecting part 50 covers multiple sub-pixels of the light-emitting unit layer 30. That is, the first connecting part 50 corresponds to multiple light-emitting parts, or an orthographic projection of the first connecting part 50 on the substrate 10 overlaps with orthographic projections of multiple light-emitting parts on the substrate 10. In this case, the cathode metal layer 35 is made of a transparent conductive material such as ITO.

Optionally, in some embodiments, the second connecting part 70 is located between the substrate 10 and the second touch electrode 353. Specifically, the second connecting part 70 is arranged at the same layer as any metal layer between the substrate 10 and the second touch electrode 353, i.e., the second connecting part 70 may be formed in a same process or process step with any metal layer between the substrate 10 and the second touch electrode 353.

Optionally, referring to FIG. 1 and FIG. 4 again, in some embodiments, the second connecting part 70 and the anode 311 are arranged at a same layer and insulated from each other. That is, the second connecting part 70 and the anode 311 are formed in a same process or process step. For example, the entire metal layer is formed first, and then the second connecting part 70 and the anode 311 are formed through photoetching.

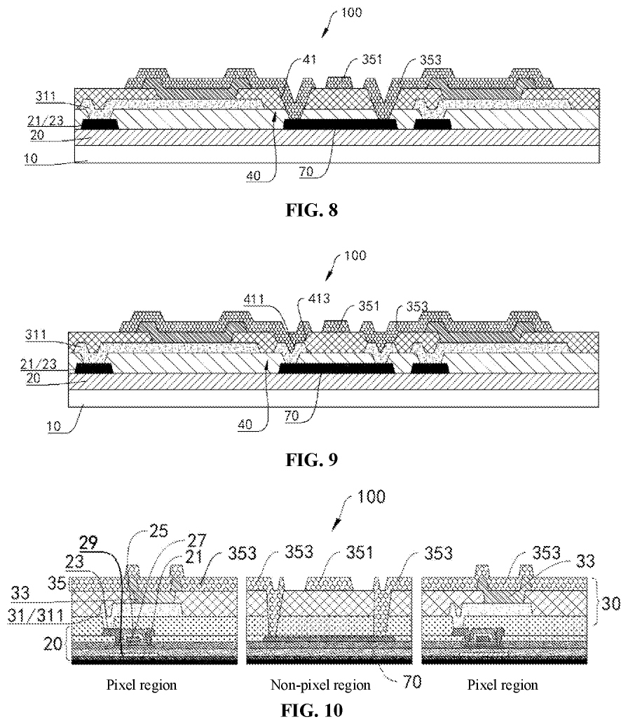

Optionally, referring to FIG. 8 and FIG. 9, in some embodiments, the second connecting part 70 is at the same layer as the source 21 and the drain 23 and insulated from the source 21 and the drain 23. That is, the second connecting part 70 is formed in the same process or process step as the source 21 and the drain 23. For example, the entire metal layer is formed first, and then the second connecting part 70, the source 21 and the drain 23 are formed through photoetching.

Referring to FIG. 8, in some embodiments, an insulating layer 40 is arranged between the second touch electrode 353 and the second connecting part 70, the insulating layer 40 is provided with a through hole 41, and the second touch electrode 353 is electrically connected to the second connecting part 70 by filling the through hole 41 with a conductive material. Specifically, the conductive material may be the same as a material of the metal layer between the second touch electrode 353 and the second connecting part 70, i.e., the material formed at the same time as the metal layer and used for filling the metal layer when other metal layers between the second touch electrode 353 and the second connecting part 70 are prepared. In addition, other metal materials may alternatively be used for filling. In the embodiment of FIG. 8, the conductive material is a material of the cathode metal layer 35.

Referring to FIG. 9, in some embodiments, the through hole 41 includes a first hole position 411 and a second hole position 413, the first hole position 411 is filled with a first conductive material, and the second hole position 413 is filled with a second conductive material. The first conductive material is electrically connected to the second connecting part 70 and the second conductive material, and the second conductive material is electrically connected to the first conductive material and the second touch electrode 353. For example, when the second connecting part 70 is arranged at the same layer as the source 21, the drain 23, the gate 25, the light shielding layer 29 or any metal layer between the substrate 10 and the anode 311, the first conductive material is the same as the material of the anode 311, and the second conductive material is the same as the material of the cathode metal layer 35. That is, the first hole position 411 is filled with the metal of the anode when the cathode metal layer 35 is prepared, and the second hole position 413 is filled with the metal of the cathode metal layer 35 when the anode 311 is prepared.

Optionally, referring to FIG. 10, in some embodiments, the second connecting part 70 and the gate 25 are arranged at a same layer and insulated from each other. That is, the second connecting part 70 and the gate 25 are formed in a same process or process step. For example, the entire metal layer is formed first, and then the second connecting part 70 and the gate 25 are formed through photoetching.

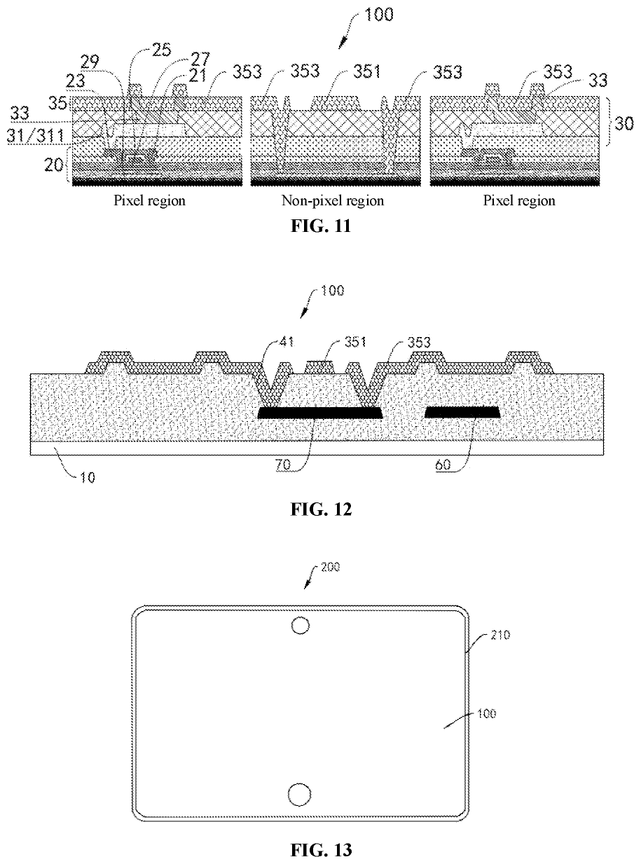

Optionally, referring to FIG. 11, in some embodiments, when the thin-film transistor has a top gate structure, the second connecting part 70 and the light shielding layer 29 are arranged at a same layer and insulated from each other. That is, the second connecting part 70 and the light shielding layer 29 are formed in a same process or process step. For example, the entire metal layer is formed first, and then the second connecting part 70 and the light shielding layer 29 are formed through photoetching.

Optionally, referring to FIG. 12, in some embodiments, the touch display panel 100 according to the embodiments of the present disclosure further includes a metal wire 60, where the metal wire 60 is located between the substrate 10 and the cathode metal layer 35, and the second connecting part 70 and the metal wire 60 are at a same layer and are insulated from each other. That is, a single layer of metal wire 60 may be arranged between the substrate 10 and the cathode metal layer 35, and the second connecting part 70 and the metal wire 60 are arranged at the same layer, i.e., the second connecting part 70 and the metal wire 60 are formed in a same process or process step. For example, the entire metal layer is formed first, and then the second connecting part 70 and the metal wire 60 are formed through photoetching.

Referring to FIG. 13, an embodiment of the present disclosure further provides an electronic device 200, including:

a device body 210; and

the touch display panel 100 according to the embodiment of the present disclosure, where the touch display panel 100 is arranged on the device body 210.

The electronic device 200 according to the present disclosure includes, but is not limited to, devices with display functions such as a display, a computer, a television, a tablet computer, a mobile phone, an e-reader, a smart watch with a display screen, a smart band and a player with a display screen.

The above are merely specific implementations of the present disclosure, but the protection scope of the present disclosure is not limited thereto. Any person skilled in the art may easily think of various equivalent modifications or replacements within the technical scope disclosed in the present disclosure, and these modifications or replacements should fall within the protection scope of the present disclosure. Therefore, the protection scope of the present disclosure should be subject to the protection scope of the claims.

What is claimed is:

1. A touch display panel, comprising:
a substrate; and
a light-emitting unit layer located on one side of the substrate, wherein the light-emitting unit layer comprises a cathode metal layer, the cathode metal layer forms first touch electrodes and second touch electrodes, and the first touch electrodes and the second touch electrodes are insulated from each other and form a mutual capacitive touch electrode.

2. The touch display panel according to claim 1, wherein the light-emitting unit layer has a light-emitting period, and the light-emitting period comprises a first time and a second time staggered from the first time; at the first time, the first touch electrodes each are configured to receive a touch drive signal, the second touch electrodes each are configured to receive a touch induction signal, or at the first time, the second touch electrodes each are configured to receive the touch drive signal, and the first touch electrodes each are configured to receive the touch induction signal; and at the second time, the first touch electrodes and the second touch electrodes are both configured to receive a display drive signal.

3. The touch display panel according to claim 1, wherein the first touch electrodes and the second touch electrodes are arranged at the same layer.

4. The touch display panel according to claim 1, further comprising a first connecting part and a second connecting part, wherein the adjacent first touch electrodes are electrically connected to each other through the first connecting part, the adjacent second touch electrodes are electrically connected to each other through the second connecting part, and the second connecting part is crossed with and insulated from the first connecting part.

5. The touch display panel according to claim 4, wherein the first connecting part is arranged at the same layer as the first touch electrodes and the second touch electrodes, and the first connecting part avoids sub-pixels of the light-emitting unit layer.

6. The touch display panel according to claim 5, wherein the second connecting part is located between the substrate and the second touch electrode.

7. The touch display panel according to claim 6, wherein an insulating layer is arranged between the second touch electrode and the second connecting part, the insulating layer is provided with a through hole, and the second touch electrode is electrically connected to the second connecting part by filling the through hole with a conductive material.

8. The touch display panel according to claim 7, wherein the through hole comprises a first hole position and a second hole position, the first hole position is filled with a first conductive material, and the second hole position is filled with a second conductive material.

9. The touch display panel according to claim 8, wherein the light-emitting unit layer comprises light-emitting units arranged in an array, the light-emitting units each comprise an anode, the first conductive material is the same as a material of the anode, and the second conductive material is the same as a material of the cathode metal layer.

10. The touch display panel according to claim 6, wherein the light-emitting unit layer comprises light-emitting units arranged in an array, the light-emitting units each comprise an anode, the anode is located between the substrate and the cathode metal layer, and the second connecting part and the anode are at the same layer and are insulated from each other.

11. The touch display panel according to claim 6, further comprising a metal wire, wherein the metal wire is located between the substrate and the cathode metal layer, and the second connecting part and the metal wire are at the same layer and are insulated from each other.

12. The touch display panel according to claim 6, further comprising a source and a drain, wherein the source and the drain are insulated from each other and arranged at the same layer at an interval, and the source and the drain are located between the substrate and the light-emitting unit; and the second connecting part is at the same layer as the source and the drain and is insulated from the source and the drain.

13. The touch display panel according to claim 6, further comprising a gate, wherein the gate is located between the substrate and the light-emitting unit, and the second connecting part and the gate are at the same layer and are insulated from each other.

14. The touch display panel according to claim 6, further comprising a light shielding layer, wherein the light shielding layer is located on a surface of the substrate facing the light-emitting unit, and the second connecting part and the light shielding layer are at the same layer and are insulated from each other.

15. An electronic device, comprising:
a device body; and
a touch display panel arranged on the device body, wherein the touch display panel comprises:
a substrate; and
a light-emitting unit layer located on one side of the substrate, wherein the light-emitting unit layer comprises a cathode metal layer, the cathode metal layer forms first touch electrodes and second touch electrodes, and the first touch electrodes and the second touch electrodes are insulated from each other and form a mutual capacitive touch electrode.

16. The electronic device according to claim 15, wherein the light-emitting unit layer has a light-emitting period, and the light-emitting period comprises a first time and a second time staggered from the first time; at the first time, the first touch electrodes each are configured to receive a touch drive signal, the second touch electrodes each are configured to receive a touch induction signal, or at the first time, the second touch electrodes each are configured to receive the touch drive signal, and the first touch electrodes each are configured to receive the touch induction signal; and at the second time, the first touch electrodes and the second touch electrodes are both configured to receive a display drive signal.

17. The electronic device according to claim 15, wherein the first touch electrodes and the second touch electrodes are arranged at the same layer.

18. The electronic device according to claim 15, wherein the touch display panel further comprises a first connecting part and a second connecting part, wherein the adjacent first touch electrodes are electrically connected to each other through the first connecting part, the adjacent second touch electrodes are electrically connected to each other through the second connecting part, and the second connecting part is crossed with and insulated from the first connecting part.

19. The electronic device according to claim 18, wherein the first connecting part is arranged at the same layer as the first touch electrodes and the second touch electrodes, and the first connecting part avoids sub-pixels of the light-emitting unit layer.

20. The electronic device according to claim 19, wherein the second connecting part is located between the substrate and the second touch electrode.
